(19) United States
(12) Patent Application Publication
(10) Pub. No.: US 2025/0248212 A1
(43) Pub. Date: Jul. 31, 2025

(54) DISPLAY APPARATUS

(71) Applicant: LG Display Co., Ltd., Seoul (KR)

(72) Inventors: Minwan KIM, Paju-si (KR); JuHyuk KIM, Goyang-si (KR); Byonghoo KIM, Paju-si (KR); Sangwook WOO, Goyang-si (KR); Jinuk LEE, Seoul (KR)

(73) Assignee: LG Display Co., Ltd., Seoul (KR)

(21) Appl. No.: 18/777,507

(22) Filed: Jul. 18, 2024

(30) Foreign Application Priority Data
Jan. 29, 2024 (KR) 10-2024-0013361

(51) Int. Cl. H10K 50/858; H10K 59/122; H10K 59/40

(52) U.S. Cl. CPC H10K 50/858; H10K 59/122; H10K 59/40

(57) ABSTRACT

The present disclosure relates to a display apparatus. More particularly, according to an aspect of the present disclosure, a display apparatus includes: a substrate; a plurality of light emitting diodes disposed on the substrate; a touch sensor disposed on the plurality of light emitting diodes; and a plurality of optical members disposed on the touch sensor, in which the touch sensor includes a plurality of bridge electrodes disposed on the plurality of light emitting diodes, an optical gap layer disposed on the bridge electrode and expose at least a part of each of the plurality of bridge electrodes, and a touch electrode disposed to be in contact with each of the plurality of exposed bridge electrodes, and the optical gap layer includes a plurality of openings corresponding to the plurality of light emitting diodes, respectively, and the plurality of optical members is disposed to fill the plurality of openings, respectively.

### CROSS-REFERENCE TO RELATED APPLICATIONS

This application claims the benefit of and the priority to Korean Patent Application No. 10-2024-0013361 filed on Jan. 29, 2024, in the Korean Intellectual Property Office, the disclosure of which is hereby incorporated by reference in its entirety.

### BACKGROUND

### 1. Technical Field

The present disclosure relates to a display apparatus, and more particularly, to a display apparatus with improved viewing angle blocking efficiency and light efficiency.

### 2. Description of the Related Art

An organic light emitting diode OLED which is a self-emitting device includes an anode and a cathode, and an organic compound layer formed therebetween. The organic compound layer is constituted by a hole transport layer HTL, a light emitting layer EML, and an electron transport layer ETL. When driving voltage is applied to the anode and the cathode, holes passing through the hole transport layer HTL and electrons passing through the electron transport layer ETL are moved to the light emitting layer EML to form an exciton, and as a result, the light emitting layer EML generates visible light. An organic light emitting display device includes an organic light emitting diode that autonomously emits light unlike a liquid crystal display device having a backlight which is a separate light source, and is variously used due to an advantage in that a response speed is fast, and light emission efficiency, luminance, and a viewing angle are large.

The organic light emitting display device is not limited in terms of the viewing angle, but in recent years, the limit of the viewing angle has been required due to the protection of privacy, the protection of information, and the like. However, since the limit of the viewing angle varies depending on whether driving is performed, and whether the driver at a driver's seat and the passenger at a passenger seat is watching the organic light emitting display device, selective viewing switching is required. In addition, in some countries, media reproduced in the passenger seat prohibits the exposure to the driver at the driver's seat, so the selective viewing angle switching is required.

In line with the requirements described above, a display apparatus which includes a viewing angle control member used to control the viewing angle and a touch sensor disposed on a display panel has been developed. However, in the display apparatus of such a structure, each of the viewing angle control devices and the touch sensor is manufactured on a separate substrate, and then stacked, so the structure is complicated and there is a limit in slimming the display apparatus. Therefore, the development of technology that internalizes the viewing angle control devices and the touch sensor in the display panel is being actively underway.

### SUMMARY

Accordingly, an object to be achieved by the present disclosure is to provide a display apparatus which has excellent viewing angle control efficiency while simplifying a stack structure by internalizing a component for controlling a viewing angle.

Another object to be achieved by the present disclosure is to maximize light extraction efficiency by reducing lost light by increasing linearity of the light.

Yet another object to be achieved by the present disclosure is to simultaneously improve luminance and viewing angle limitation characteristics which have a trade off relationship.

Objects of the present disclosure are not limited to the above-mentioned objects, and other objects, which are not mentioned above, can be clearly understood by those skilled in the art from the following descriptions.

To achieve these and other advantages and in accordance with objects of the disclosure, as embodied and broadly described herein, a display apparatus includes: a substrate; a plurality of light emitting diodes disposed on the substrate; a touch sensor disposed on the plurality of light emitting diodes; and a plurality of optical members disposed on the touch sensor, in which the touch sensor includes a plurality of bridge electrodes disposed on the plurality of light emitting diodes, an optical gap layer disposed on the bridge electrode and expose at least a part of each of the plurality of bridge electrodes, and a touch electrode disposed to be in contact with each of the plurality of exposed bridge electrodes, and the optical gap layer includes a plurality of openings corresponding to the plurality of light emitting diodes, respectively, and the plurality of optical members is disposed to fill the plurality of openings, respectively.

Other detailed matters of the example embodiments are included in the detailed description and the drawings.

According to the present disclosure, a display apparatus which internalizes a component for controlling a viewing angle by applying an optical gap layer to a touch sensor and applying an optical member onto the touch sensor is provided.

According to the present disclosure, a display apparatus which is disposed so that the optical member is disposed in an opening formed in the optical gap layer and has improved light extraction efficiency by reducing lost light by increasing linearity of light is provided.

According to the present disclosure, a display apparatus in which a touch electrode is disposed to cover a top surface and a side surface of the optical gap layer, and reflects light which may be lost in a side direction toward a front surface to simultaneously improve viewing angle limitation efficiency and luminance is provided.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

The effects according to the present disclosure are not limited to the contents exemplified above, and more various effects are included in the present specification.

It is to be understood that both the foregoing general description and the following detailed description of the present disclosure are merely by way of example and are intended to provide further explanation of the inventive concepts as claimed.

### BRIEF DESCRIPTION OF DRAWINGS

The accompanying drawings, which are included to provide a further understanding of the present disclosure and are incorporated in and constitute a part of this application, illustrate embodiments of the present disclosure and together with the description serve to explain the principles of the present disclosure.

FIG. 1 is a schematic cross-sectional view for a display apparatus according to an example embodiment of the present disclosure;

FIG. 2 is an enlarged cross-sectional view for one subpixel in the display apparatus according to an example embodiment of the present disclosure;

FIG. 3 is a view for explaining a plane shape of an opening formed in an optical gap layer in the display apparatus according to an example embodiment of the present disclosure;

FIG. 4 is a view schematically illustrating a second portion of a first lens in the display apparatus according to an example embodiment of the present disclosure;

FIG. 5 is a view schematically illustrating a second portion of a second lens in the display apparatus according to an example embodiment of the present disclosure;

FIG. 6 is a view schematically illustrating operations of a wide-view angle mode and a narrow-view angle mode in the display apparatus according to an example embodiment of the present disclosure; and

FIG. 7 is an enlarged cross-sectional view for one subpixel in the display apparatus according to another example embodiment of the present disclosure.

### DETAILED DESCRIPTION

Reference will now be made in detail to some of the examples and embodiments of the present disclosure illustrated in the accompanying drawings. Wherever possible, the same reference numbers will be used throughout the drawings to refer to the same or like parts.

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto.

Like reference numerals generally denote like elements throughout the specification. Further, following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display apparatus according to example embodiments of the present disclosure will be described in detail with reference to accompanying drawings.

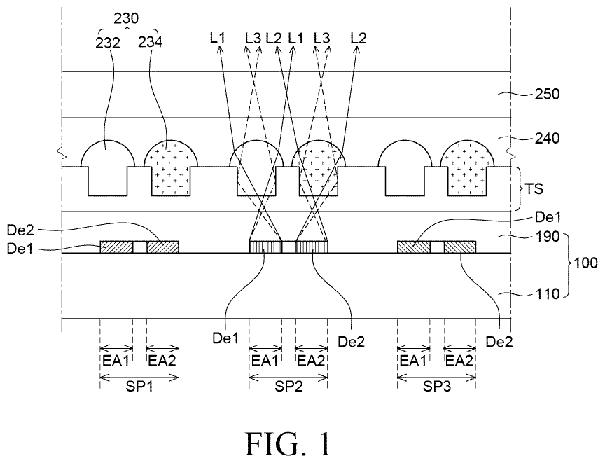

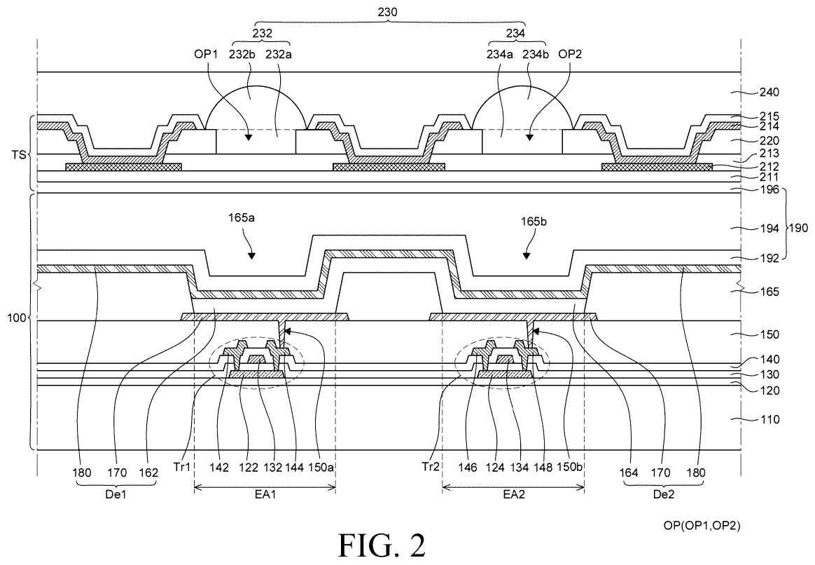

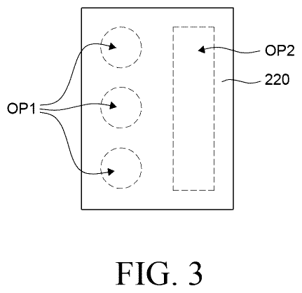

FIG. 1 is a schematic cross-sectional view for a display apparatus according to an example embodiment of the present disclosure. FIG. 2 is an enlarged cross-sectional view for one subpixel in the display apparatus according to an example embodiment of the present disclosure, and FIG. 3 is a view for explaining a plane shape of an opening formed in an optical gap layer in the display apparatus according to an example embodiment of the present disclosure.

As illustrated in FIGS. 1 and 2, the display apparatus according to an example embodiment of the present disclosure includes a display panel 100, a touch sensor TS, an optical member 230, and a planarization film 240, and the touch sensor TS includes a touch buffer layer 211, a bridge electrode 212, a touch insulation layer 213, an optical gap layer 220, and a touch electrode 215.

The display panel 100 includes a substrate 110, a plurality of thin film transistors Tr1 and Tr2, a plurality of light emitting diodes De1 and De2, and an encapsulation layer 190.

A plurality of subpixels is defined on the substrate 110. For example, a first subpixel SP1, a second subpixel SP2, and a third subpixel SP3 are defined on the substrate 110. Each of the first subpixel SP1, the second subpixel SP2, and the third subpixel SP3 has a first emission area EA1 and a second emission area EA2.

The first light emitting diode De1 is provided in the first emission area EA1, and the second light emitting diode De2 is provided in the second emission area EA2.

The first subpixel SP1, the second subpixel SP2, and the third subpixel SP3 may be a red subpixel, a green subpixel, and a blue subpixel, respectively. Therefore, the first light emitting diode De1 and the second light emitting diode De2 of the first subpixel SP1 may emit red light, the first light emitting diode De1 and the second light emitting diode De2 of the second subpixel SP2 may emit green light, and the light emitting diode De1 and the second light emitting diode De2 of the third subpixel SP3 may emit blue light. An emission color of each subpixel is not limited to the above-described example, but may be changed according to an example embodiment.

The encapsulation layer 190 having a flat top surface may be provided on the top of the first light emitting diode De1 and the second light emitting diode De2. The encapsulation layer 190 may protect the first light emitting diode De1 and the second light emitting diode De2 from moisture and oxygen.

A specific configuration of the display panel 100 will be described later in detail.

The touch sensor TS is provided on the display panel 100 in order to grant a touch sensing function. As described above, the touch sensor TS may include a touch buffer layer 211, a bridge electrode 212, a touch insulation layer 213, an optical gap layer 220, a touch electrode 214, and a touch protection layer 215.

The touch electrode 214 as an electrode that senses a touch input may be constituted by a plurality of sensing electrodes and a plurality of driving electrodes, and senses a capacitance change therebetween to detect touch coordinates.

In the display apparatus according to an example embodiment of the present disclosure, a touch panel including a bridge electrode and a touch electrode may have a touch on encapsulation structure in which the touch sensor TS is directly disposed on the encapsulation layer 190 without a separate substrate and/or adhesive member. However, the present disclosure is not limited thereto.

The optical gap layer 220 is provided in the touch sensor TS. The optical gap layer 220 secures an optical gap between the first light emitting diode De1 and the second light emitting diode De2, and lenses 232 and 234 of the optical member 230 to refract light from the first light emitting diode De1 and the second light emitting diode De2 in a specific direction by the lenses 232 and 234. As a result, the light extraction efficiency is improved. A specific configuration of the touch sensor TS will be described later in detail.

The optical member 230 is provided on the optical gap layer 220. The optical member 230 includes a first lens 232 and a second lens 234. The first lens 232 is disposed in the first emission area EA1 to reflect the light from the first light emitting diode De1 in a specific direction. The second lens 234 is disposed in the second emission area EA2 to reflect the light from the second light emitting diode De2 in a specific direction.

For example, the first lens 232 and the second lens 234 may have different shapes. As a result, first light L1 emitted from the first light emitting diode De1 of each of the subpixels SP1, SP2, and SP3 is refracted and output at a specific angle by the first lens 232. In addition, second light L2 emitted from the second light emitting diode De2 of each of the subpixels SP1, SP2, and SP3 is refracted and output at a specific angle by the second lens 234. As a result, a viewing angle of each of the subpixels SP1, SP2, and SP3 may be limited.

Viewing angle of the first lens 232 and the second lens 234 may be different. The first lens 232 and the second lens 234 may implement a wide view and a narrow view by selective driving. This will be described later in detail.

Meanwhile, third light L3 at a specific angle emitted from the first light emitting diode De1 of each subpixel SP1, SP2, or SP3 and fourth light L4 at a specific angle emitted from the second light emitting diode De2 are blocked by the bridge electrode 212 and/or the touch electrode 214 of the touch sensor TS not to be emitted to the outside of the display apparatus. In this case, there may be a difficulty in improving the light extraction efficiency simultaneously with maintaining a viewing angle limitation effect to be high.

In the display apparatus according to an example embodiment of the present disclosure, each of the first lens 232 and the second lens 234 are disposed to fill the opening provided in the optical gap layer 220 of the touch sensor TS. Therefore, the third light L3 at the specific angle emitted from the first light emitting diode De1 is fully reflected on an interface where the optical gap layer 220 and the first lens 232 are in contact with each other. Further, the fourth light L4 at the specific angle emitted from the second light emitting diode De2 is fully reflected on an interface where the optical gap layer 220 and the second lens 234 are in contact with each other. Therefore, in the display apparatus according to an example embodiment of the present disclosure, the third light L3 and the fourth light L4 at the specific angles are not lost, but may be fully reflected on the interfaces where the optical gap layer 220, and the lenses 232 and 234 are in contact with each other, and emitted to the outside. Accordingly, according to an example embodiment of the present disclosure, the viewing angle limitation effect and the light extraction efficiency which have the trade off relationship may be simultaneously improved.

In order to increase extraction efficiency of the light emitted from the light emitting diodes De1 and De2, a refractive index of the optical member 230 may be formed to be higher than a refractive index of the optical gap layer 220. For example, the refractive index of the optical gap layer 220 may be 1.30 or more and 1.45 or less, and the refractive index of the optical member 230 may be 1.60 or more and 1.75 or less. In this case, a light collection effect emitted from the light emitting diodes De1 and De2 is excellent, and there is an effect in that the light extraction efficiency and the luminance are improved by minimizing light extinguished in the display apparatus.

For example, the optical member 230 including the first lens 232 and the second lens 234 may be formed to contain an acrylic resin, but is not limited thereto. The acrylic resin has an advantage of being transparent, and excellent optical characteristics.

The optical member 230 may be formed to further include at least one repetition unit among repetition units represented by Formulas 1 to 4 below. The repetition units represented by Formulas 1 to 4 below include a chemical structure having a high refractive index to improve light collection efficiency of light.

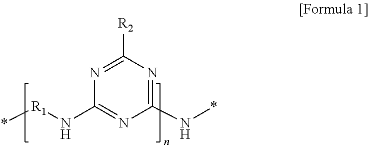

In Formula 1, R₁ may be selected from a linear alkyl group, a branched alkyl group, a cyclo alkyl group, or an aryl group, and R₂ may be selected from the linear alkyl group or the branched alkyl group, and n may be an integer of 1 or more and 100 or less.

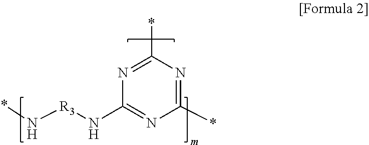

In Formula 2, R₃ may be selected from the linear alkyl group, the branched alkyl group, the cyclo alkyl group, or the aryl group, and m may be the integer of 1 or more and 100 or less.

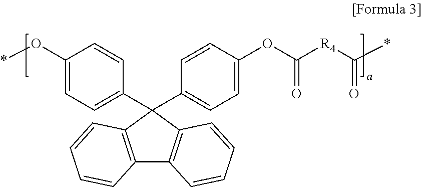

In Formula 3, R₄ may be selected from the linear alkyl group, the branched alkyl group, or the aryl group, and a may be the integer of 1 or more and 100 or less.

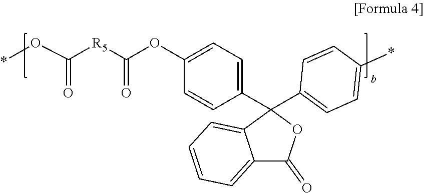

In Formula 4, R₅ may be selected from the linear alkyl group, the branched alkyl group, or the aryl group, and b may be the integer of 1 or more and 100 or less.

The planarization film 240 is provided on the top of the optical member 230 to protect the first lens 232 and the second lens 234. The planarization film 240 is made of an organic insulation material, and has a planarized upper surface. In addition, a refractive index of the planarization film 240 may be smaller than refractive indexes of the first lens 232 and the second lens 234. In this case, the luminance and the light extraction efficiency of the display apparatus are excellent.

As an example, the planarization film 240 may be made of photo acryl, benzocyclobutene (BCB), polyimide (PI), or polyamide (PA), but is not limited thereto.

Although not illustrated in the drawings, an optical function layer such as a polarization layer may be disposed as at least one layer on the top of the planarization film 240. The polarization layer serves to suppress external light from being reflected on the display panel 100, and then emitted to the outside again by converting a polarization state of external light incident on the display panel 100.

The display panel 100 and the touch sensor TS of the display apparatus according to an example embodiment of the present disclosure will be described in detail with reference to FIGS. 1 and 2.

As illustrated in FIG. 2, the display panel 100 of the display apparatus according to an example embodiment of the present disclosure includes a substrate 110, a plurality of thin film transistors Tr1 and Tr2, a plurality of light emitting diodes De1 and De2, and an encapsulation layer 190.

Each of the subpixels SP1, SP2, and SP3 on the substrate 110 includes a first emission area EA1 and a second emission area EA2. The substrate 110 may be a glass substrate or a plastic substrate. For example, as the plastic substrate, polyimide (PI) may be used, but the present disclosure is not limited thereto. When the plastic substrate is used as the substrate 110, a multi-layered structure substrate in which a polyimide layer and an inorganic barrier layer are alternately stacked may be used in order to ensure rigidity and barrier characteristics, but the present disclosure is not limited thereto.

A substrate buffer layer 120 is disposed on the top of the substrate 110. The substrate buffer layer 120 is substantially formed on an entire surface of the substrate 110. The substrate buffer layer 120 blocks moisture or foreign materials from being introduced into the thin film transistors Tr1 and Tr2 from the substrate 110.

For example, the substrate buffer layer 120 may be made of an inorganic material such as silicon oxide (SiO₂) or silicon nitride (SiNₓ), and configured as a single layer or multiple layers.

A first semiconductor layer 122 and a second semiconductor layer 124 which are patterned are formed in the first emission area EA1 and the second emission area EA2 on the top of the substrate buffer layer 120, respectively. Each of the first semiconductor layer 122 and the second semiconductor layer 124 may be independently made of an oxide semiconductor material or a polycrystalline silicon.

When the first semiconductor layer 122 and the second semiconductor layer 124 are made of an oxide semiconductor material, a light blocking pattern may be further formed on the bottom of the first and second semiconductor layers 122 and 124. The light blocking pattern blocks light incident on the first and second semiconductor layers 122 and 124 to suppress the first and second semiconductor layers 122 and 124 from being deteriorated by light.

When the first and second semiconductor layers 122 and 124 are made of the polycrystalline silicon, impurities may be doped on both edges of each of the first and second semiconductor layers 122 and 124.

A gate insulating film 130 made of an inorganic insulation material is disposed on the top of the first and second semiconductor layers 122 and 124. The gate insulating film 130 may be made of the inorganic insulation material such as silicon oxide (SiO₂) or silicon nitride (SiNx).

A first gate electrode 132 and a second gate electrode 134 made of a conductive material such as metal are formed on the top of the gate insulating film 130 to correspond to the first semiconductor layer 122 and the second semiconductor layer 124, respectively.

In FIG. 2, it is illustrated that the gate insulating film 130 is substantially formed on the entire surface of the substrate 110, but as another example, the gate insulating film 130 may also be patterned in the same shape as the first gate electrode 132 and the second gate electrode 134.

An interlayer insulation film 140 made of the inorganic insulation material is substantially formed on the entire surface of the substrate 110 on the top of the first and second gate electrodes 132 and 134. The interlayer insulation film 140 may be made of the inorganic insulation material such as silicon oxide (SiO₂) or silicon nitride (SiNx), or made of an organic insulation material such as photo acryl or benzocyclobutene.

The interlayer insulation film 140 has a contact hole for exposing both top surfaces of each of the first and second semiconductor layers 122 and 124. The contact hole may also be formed in the gate insulating film 130. A first source electrode 142 and a first drain electrode 144, and a second source electrode 146 and a second drain electrode 148 which are made of the conductive material such as the metal are formed in the first emission area EA1 and the second emission area EA2, respectively on the top of the interlayer insulation film 140.

The first source electrode 142 and the first drain electrode 144 are in contact with both sides of the first semiconductor layer 122 through the contact hole of the interlayer insulation film 140, and the second source electrode 146 and the second drain electrode 148 are in contact with both sides of the second semiconductor layer 124 through the contact hole of the interlayer insulation film 140.

The first semiconductor layer 122, the first gate electrode 132, the first source electrode 142, and the first drain electrode 144 constitute the first thin film transistor Tr1, and the second semiconductor layer 124, the second gate electrode 134, the second source electrode 146, and the second drain electrode 148 constitute the second thin film transistor Tr2.

One or more thin film transistors having the same structure as the first and second thin film transistors Tr1 and Tr2 may be further formed on the substrate 110 of each of the sub pixels SP1, SP2, and SP3, but the present disclosure is not limited thereto.

A protection film 150 made of an insulation material is substantially formed on the entire surface of the substrate 110 on the top of the first source electrode 142 and the first drain electrode 144, and the second source electrode 146 and the second drain electrode 148. The protection film 150 may be made of the organic insulation material such as acryl photo or benzocyclobutene. The protection film 150 has a flat top surface.

As necessary, optionally, an insulating film made of the inorganic insulation material such as silicon oxide (SiO₂) or silicon nitride (SiNx) may be further formed between the first thin film transistor Tr1 and the second thin film transistor Tr2, and the protection film 150.

The protection film 150 has a first drain contact hole 150a and a second drain contact hole 150b for exposing the first drain electrode 144 and the second drain electrode 148, respectively.

A first anode electrode 162 and a second anode electrode 164 which are made of a conductive material having a comparatively high work function are formed on the top of the protection film 150. The first anode electrode 162 is positioned in the first emission area EA1, and is in contact with the first drain electrode 144 through the first drain contact hole 150a. In addition, the second anode electrode 164 is positioned in the second emission area EA2, and is in contact with the second drain electrode 148 through the second drain contact hole 150b. In the drawings, it is illustrated that the first anode electrode 162 and the second anode electrode 164 are formed to be in contact with the first drain electrode 144 and the second electrode 148, respectively, but the present disclosure is not limited thereto. As another example, the first anode electrode 162 may be formed to be electrically connected to the first source electrode 142, and the second anode electrode 164 may also be formed to be electrically connected to the second source electrode 146.

As an example, each of the first anode electrode 162 and the second anode electrode 164 may be made of a transparent conductive material such as indium tin oxide (ITO) or indium zinc oxide (IZO), but is not limited thereto.

Meanwhile, the display panel 100 according to an example embodiment of the present disclosure may be a top emission type in which light of the plurality of light emitting diodes De1 and De2 is output in an opposite direction to the substrate 110, and as a result, each of the first anode electrode 162 and the second anode electrode 164 may further include a reflection electrode or a reflection layer made of a metallic material having a high reflectance below the transparent conductive material. For example, the reflection electrode or the reflection layer may be made of an aluminum-palladium-copper (APC) alloy, silver (Ag), or aluminum (Al). At this time, each of the first anode electrode 162 and the second anode electrode 164 may have a triple-layer structure of ITO/APC/ITO, ITO/Ag/ITO, or ITO/Al/ITO.

A bank 165 made of the insulation material is formed on the top of the first anode electrode 162 and the second anode electrode 164. The bank 165 overlaps edges of the first anode electrode 162 and the second anode electrode 164, and covers the edges of the first anode electrode 162 and the second anode electrode 164. The bank 165 has a first opening 165a and a second opening 165b for exposing the first anode electrode 162 and the second anode electrode 164.

In the present disclosure, the bank 165 has a single-layer structure, but the bank 165 may also have a double-layer structure. For example, the bank 165 may also have a double-layer structure including a lower hydrophilic bank and an upper hydrophobic bank.

Light emitting layers 170 are formed on the tops of the first anode electrode 162 and the second anode electrode 164 exposed through the first opening 165a and the second opening 165b of the bank 165. The light emitting layer 170 on the top of the first anode electrode 162 and the light emitting layer 170 on the top of the second anode electrode 164 are connected and integrated. However, the present disclosure is not limited thereto, and the light emitting layer 170 on the top of the first anode electrode 162 and the light emitting layer 170 on the top of the second anode electrode 164 may also be separated from each other.

The light emitting layer 170 may include a first charge auxiliary layer, a light-emitting material layer, and a second charge auxiliary layer positioned sequentially from the tops of the first anode electrode 162 and the second anode electrode 164. The light-emitting material layer may be made of any one of red, green, and blue light-emitting materials, and is not limited thereto. The light-emitting material may be an organic light-emitting material such as a phosphorus compound or a fluorescent compound. However, the present disclosure is not limited thereto, and an inorganic light-emitting material such as a quantum dot may also be used.

The first charge auxiliary layer may include at least one of a hole injection layer HIL and a hole transport layer HTL. The second charge auxiliary layer may include at least one of an electron injection layer EIL and an electron transport layer ETL.

A cathode electrode 180 made of a conductive material having a comparatively low work function is substantially formed on the entire surface of the substrate 110 on the top of the light emitting layer 170. Here, the cathode electrode 180 may be made of aluminum or magnesium, silver, or an alloy thereof. At this time, the cathode electrode 180 has a relatively thin thickness so that light from the light emitting layer 170 may be transmitted.

As another example, the cathode electrode 180 may also be made of a transparent conductive material such as indium-gallium-oxide (IGO), indium tin oxide (ITO), or indium zinc oxide (IZO), but is not limited thereto.

The display panel 100 according to an example embodiment of the present disclosure may be a top emission type in which the light from the light emitting layers 170 of the first light emitting diode De1 and the second light emitting diode De2 is output in an opposite direction to the substrate 110, i.e., to the outside through the cathode electrode 180. Since the top emission type may have a border emission area than a bottom emission type of the same area, the top emission type may improve luminance and reduce power consumption.

The encapsulation layer 190 is substantially formed on the entire surface of the substrate 110 on the top of the cathode electrode 180. The encapsulation layer 190 suppresses moisture or oxygen from being introduced into the first light emitting diode De1 and the second light emitting diode De2 from the outside. The encapsulation layer 190 may be formed as a single layer or multiple layers. For example, the encapsulation layer 190 may have a stacking structure of a first inorganic film 192, an organic film 194, and a second inorganic film 196. Here, the organic film 194 may be a layer that covers foreign materials generated during a manufacturing process.

The touch sensor TS is provided on the top of the encapsulation layer 190, and as described above, the touch sensor TS includes a touch buffer layer 211, a bridge electrode 212, a touch insulation layer 213, an optical gap layer 220, a touch electrode 214, and a touch protection layer 215.

The touch buffer layer 211 is substantially formed on the entire surface of the substrate 110 on the top of the encapsulation layer 190. The touch buffer layer 211 suppresses penetration of a chemical liquid such as a development liquid or an etching liquid, or foreign materials in a step of forming the bridge electrode 212 and the touch electrode 214 of the touch sensor TS to protect the light emitting diodes De1 and De2 not to be damaged. Further, the touch buffer layer 211 provides adhesive force to suppress lifting of the bridge electrode 212. Further, the touch buffer layer 211 may minimize a formation failure of the bridge electrode 121 and the touch electrode 214.

For example, the touch buffer layer 211 may be made of the inorganic material such as silicon oxide (SiO₂) or silicon nitride (SiNₓ). The touch buffer layer 211 may be formed as the single layer or multiple layers.

A plurality of bridge electrodes 212 is formed on the touch buffer layer 211. The bridge electrode 212 is formed to correspond to at least a part between the first to third subpixels SP1, SP2, and SP3, and between the first emission area EA1 and the second emission area EA2.

The bridge electrode 212 electrically connects at least some of a plurality of touch electrodes 214 formed on the touch insulation layer 213 made of the insulation material. As described above, the plurality of touch electrodes 214 includes a plurality of sensing electrode and a plurality of driving electrodes. The plurality of sensing electrodes and the plurality of driving electrodes are disposed on the same plane, and the bridge electrode 212 is disposed on a different layer from the plurality of touch electrodes 214 to electrically connect adjacent sensing electrodes or adjacent driving electrodes in a region where the sensing electrode and the driving electrode intersect each other. Therefore, the bridge electrode 212 suppresses the sensing electrode and the driving electrode from being shortened in the region where the sensing electrode and the driving electrode intersect each other.

The bridge electrode 212 may be made of metal selected from molybdenum (Mo), aluminum (Al), chromium (Cr), gold (Au), titanium (Ti), nickel (NI), copper (Cu), neodymium (Nd), tungsten (W), and an alloy thereof, but is not limited thereto. The bridge electrode 212 may be formed as a single layer or multiple layers.

The touch insulation layer 213 may be formed on the top of the bridge electrode 212. The touch insulation layer 213 is substantially formed on the entire surface of the substrate 110. The touch insulation layer 213 insulates the bridge electrode 212, and the sensing electrode or the driving electrode among the plurality of touch electrodes 214, and is disposed between the bridge electrodes 212 to insulate adjacent bridge electrodes 212 from each other. Since the optical gap layer 220 disposed on the touch insulation layer 213 is made of the insulation material, the touch insulation layer 213 may be selectively omitted as necessary.

The touch insulation layer 213 includes a contact hole to electrically connect the bridge electrode 212 and the touch electrode 214 to each other. The touch insulation layer 213 overlaps the edge of the bridge electrode 212, and is formed to cover the edge of the bridge electrode 212. The contact hole of the touch insulation layer 213 exposes a top surface of the bridge electrode 212, and the bridge electrode 212 is in contact with the touch electrode 214 through the contact hole.

The touch insulation layer 213 may be made of the inorganic insulation material such as silicon oxide (SiO₂) or silicon nitride (SiNx). The touch insulation layer 213 may be formed as a single layer or multiple layers.

The optical gap layer 220 is formed on the top of the touch insulation layer 213. As described above, the optical gap layer 220 secures an optical gap between the first light emitting diode De1 and the second light emitting diode De2, and lenses 232 and 234 of the optical member 230 to refract light from the first light emitting diode De1 and the second light emitting diode De2 in a specific direction by the lenses 232 and 234, thereby improving the light extraction efficiency.

The optical gap layer 220 contains at least one selected from acrylic resin, siloxane-based resin, polyimide-based resin, polyamide-based resin, cycloolefin-based resin, polyester-based resin, epoxy resin, silicon-based resin, and fluorine-based resin. Preferably, the optical gap layer 220 may include, but is not limited thereto, the acrylic resin or the siloxane-based resin having excellent optical characteristics and easy to obtain, but is not limited thereto.

The optical gap layer 220 includes a plurality of openings OP at locations corresponding to the first emission area EA1 and the second emission area EA2 of each of the subpixels SP1, SP2, and SP3, respectively. At least a part of the optical member 230 is disposed in each of the plurality of openings OP. Therefore, a part of the light emitted from the first light emitting diode De1 and the second light emitting diode De2 may be fully reflected on an interface where the optical gap layer 220 and the optical member 230 are in contact with each other. According to an example embodiment of the present disclosure, full reflection occurs on the interface where the optical gap layer 220 and the optical member 230 are in contact with each other to improve the light extraction efficiency.

The plurality of openings OP includes a first opening OP1 corresponding to the first emission area EA1 and a second opening OP2 corresponding to the second emission area EA2. At least a part of the first lens 232 is disposed in the first opening OP1. At least a part of the second lens 234 is disposed in the second opening OP2.

For example, a plane shape of the first opening OP1 may be a circular shape, but is not limited thereto. For example, a plane shape of the second opening OP2 may be a rectangular shape, but is not limited thereto. As another example, the plane shape of the first opening OP1 may also be formed in a polygonal shape such as a square shape, a quadrangular shape, a triangular shape, etc. Further, the plane shape of the second opening OP2 may also be formed in an oval shape. The touch electrode 214 is disposed to cover the top surface of the bridge electrode 212 and at least a part of the optical gap layer 220 exposed by the contact hole of the touch insulation layer 213 and the contact hole of the optical gap layer 220 formed to overlap each other. The touch electrode 214 is in contact with the top surface of the bridge electrode 212 exposed by the contact hole of the touch insulation layer 213 and the contact hole of the optical gap layer 220. The touch electrode 214 is disposed to cover an end of the optical gap layer 220 adjacent to the bridge electrode 212 and an edge of the top of the optical gap layer 220.

The touch electrode 214 is formed to correspond to spaces between adjacent first to third subpixels SP1, SP2, and SP3 or formed to correspond to a space between the first emission area EA1 and the second emission area EA2 so as to suppress an influence on light emission efficiency of the first emission area EA1 and the second emission area EA2.

As an example, the touch electrode 214 may be formed as a reflection electrode including metal selected from aluminum (Al), silver (Ag), copper (Cu), and an alloy including one or more of them. For example, the touch electrode 214 may be formed to include one or more metal selected from silver (Ag), aluminum (Al), or an aluminum-palladium-copper (APC) alloy, but is not limited thereto. The touch electrode 214 may be formed as a single layer or multiple layers.

The end of the optical gap layer 220 which is in contact with the touch electrode 214 may be formed to have a step shape. That is, the end of the optical gap layer 220, which is in contact with the touch electrode 214 has a double step structure. Therefore, the contact hole formed in the optical gap layer 220 may have an upper width larger than a lower width. That is, the contact hole formed in the optical gap layer 220 is formed so that a width increases from the bottom to the top.

The touch electrode 214 may be formed through a deposition process after the optical gap layer 220 is formed. The optical gap layer 220 should be formed with a sufficient thickness to secure optical gaps between the first light emitting diode De1 and the second light emitting diode De2, and the lenses 232 and 234 of the optical member 230. For example, the thickness of the optical gap layer 220 may be 2 μm or more and 20 μm or less. In this case, sufficient optical gaps are secured between the first light emitting diode De1 and the second light emitting diode De2, and the optical member 230 to improve efficiency. However, as the thickness of the optical gap layer 220 is larger, a step coverage of the touch electrode 214 decreases. Therefore, the touch electrode 214 is not deposited with a uniform thickness at the end of the optical gap layer 220, and furthermore, a problem in that the touch electrode 214 is disconnected may occur.

When the end of the optical gap layer 220, which is in contact with the touch electrode 214 is formed in a step structure, the step coverage of the touch electrode 214 is improved due to an effect in which a gradient of the end of the optical gap layer 220 becomes gentle, so the thickness of the touch electrode 214 may be formed to be uniform, and there is an advantage in that touch characteristics are excellent by suppressing a failure such as disconnection.

The touch protection layer 215 is formed on the top of the touch electrode 214. The touch protection layer 215 is disposed to cover the touch electrode 214. The top surface of the touch protection layer 215 may be disposed to be lower than the top surface of the optical member 230. That is, the optical member 230 may be disposed to protrude toward an upper portion than the top surface of the touch protection layer 215. In FIG. 2, it is illustrated that the touch protection layer 215 is not disposed in a region which overlaps the optical member 230, but the present disclosure is not limited thereto. As another example, the touch protection layer 215 covers the top surfaces of the touch electrode 214 and the optical member 230 to be substantially formed on the entire surface of the substrate 110. The touch protection layer 215 protects the touch electrode 214 from outdoor air such as moisture or oxygen, and foreign materials. Further, the touch protection layer 215 protects the touch electrode 214 from the chemical liquid such as the etching liquid in the process of forming the optical member 230.

The touch protection layer 215 may be made of the inorganic insulation material or the organic insulation material, and a layer made of the inorganic insulation material and a layer made of the organic insulation material may also be disposed alternately.

For example, the touch protection layer 215 may be made of an inorganic insulation material such as silicon nitride (SiNx), silicon oxide (SiOₓ), aluminum oxide (AlOₓ), silicon oxynitride (SiON), etc., or the organic insulation material such as the acrylic resin, the polyester-based resin, the epoxy resin, the silicon-based resin, etc., but is not limited thereto. The touch insulation layer 215 may be formed as a single layer or multiple layers.

The optical member 230 is provided on the optical gap layer 220. As described above, the optical member 230 includes the first lens 232 disposed in the first emission area EA1 and the second lens 234 disposed in the second emission area EA2. The first lens 232 and the second lens 234 may be different in terms of a viewing angle, and may implement a wide view and a narrow view by selective driving. This will be described later in detail.

As described above, the optical gap layer 220 includes a plurality of openings OP at locations corresponding to the first emission area EA1 and the second emission area EA2 of each of the subpixels SP1, SP2, and SP3, respectively. At least a part of the optical member 230 is filled in each of the plurality of openings OP. The plurality of openings OP includes a first opening OP1 corresponding to the first emission area EA1 and a second opening OP2 corresponding to the second emission area EA2. At least a part of the first lens 232 is disposed in the first opening OP1, and at least a part of the second lens 234 is disposed in the second opening OP2.

The first lens 232 includes a first part 232a and a second part 232b. The first part 232a of the first lens 232 is disposed to fill the first opening OP1 corresponding to the first emission area EA1. The second lens 234 includes a first part 234a and a second part 234b. The first part 234a of the second lens 234 is disposed to fill the second opening OP2 corresponding to the second emission area EA2. Therefore, in the first lens 232, a plane shape of the first part 232a is the same as a plane shape of the first opening OP1, and in the second lens 234, a plane shape of the first part 234a is the same as a plane shape of the second opening OP2. Further, a thickness of the first part 232a of the first lens 232 may be the same as a thickness of the first opening OP1, and a thickness of the first part 234a of the second lens 234 may be the same as a thickness of the second opening OP2. As such, as the first part 232a of the first lens 232 is disposed in the first opening OP1 of the optical gap layer 220, and the first part 234a of the second lens 234 is disposed in the second opening OP2, light may not be output to the outside, and lost light may be minimized.

As described above, the first lens 232 and the second lens 234 have a higher refractive index than the optical gap layer 220. Therefore, light L3 incident at a specific angle among the light emitted from the first emission area EA1 may be fully reflected on an interface between the optical gap layer 220, and the first part 232a of the first lens 232, and output to the outside. Further, light L4 incident at a specific angle among the light emitted from the second emission area EA2 may be fully reflected on an interface between the optical gap layer 220, and the first part 234a of the second lens 234, and output to the outside. As a result, an effect in that the luminance is improved while maintaining the viewing angle limitation characteristics to be high is provided.

In order to effectively induce full reflection on each of the interface between the optical gap layer 220, and the first part 232a of the first lens 232 and the interface between the optical gap layer 220, and the first part 234a of the second lens 234, it is necessary to sufficiently secure optical gaps between the first light emitting diode De1 and the first lens 232, and between the second light emitting diode De2 and the second lens 234. Therefore, it may be preferable that straight distances from a bottom surface of the optical member 230 to top surfaces of the light emitting diodes De1 and De2 are formed to be larger than widths of the emission regions of the plurality of respective light emitting diodes De1 and De2. Therefore, the straight distance from the bottom surface of the first lens 232 to the top surface of the first light emitting diode De1 may be larger than the width of the emission region of the first light emitting diode De1. The width of the emission region of the first light emitting diode De1 may not be covered by the bank 165, but may be defined as a width of the exposed first anode electrode 162. In addition, the straight distance from the bottom surface of the second lens 234 to the top surface of the second light emitting diode De1 may be larger than the width of the emission region of the second light emitting diode De2. The width of the emission region of the second light emitting diode De2 may not be covered by the bank 165, but may be defined as a width of the exposed second anode electrode 164. In this case, the optical gaps between the first light emitting diode De1 and the first lens 232, and between the second light emitting diode De2 and the second lens 234 are sufficient, and the full reflection occurs on the interface between the optical gap layer 220, and the first part 232a of the first lens 232 and the interface between the optical gap layer 220, and the first part 234a of the second lens 234 to improve the light extraction efficiency.

The second part 232b of the first lens 232 is disposed to cover the first part 232a of the first lens 232. The second part 232b of the first lens 232 may be disposed to cover at least a part of the top surface of the optical gap layer 220 adjacent to the first opening OP1. Therefore, the width of the second part 232b of the first lens 232 is larger than the width of the first opening OP1. The second part 234b of the second lens 234 is disposed to cover the first part 234a of the second lens 234. The second part 234b of the second lens 234 may be disposed to cover at least a part of the top surface of the optical gap layer 220 adjacent to the second opening OP2. Therefore, the width of the second part 234b of the second lens 234 is larger than the width of the second opening OP2.

For example, the second part 232b of the first lens 232 may be a half-spherical lens and the second part 234b of the second lens 234 may be a half-cylindrical lens. As a result, first light L1 emitted from the first light emitting diode De1 of each of the subpixels SP1, SP2, and SP3 is refracted and output at a specific angle by the first lens 232. In addition, second light L2 emitted from the second light emitting diode De2 of each of the subpixels SP1, SP2, and SP3 is refracted and output at a specific angle by the second lens 234. As a result, a viewing angle of each of the subpixels SP1, SP2, and SP3 may be limited.

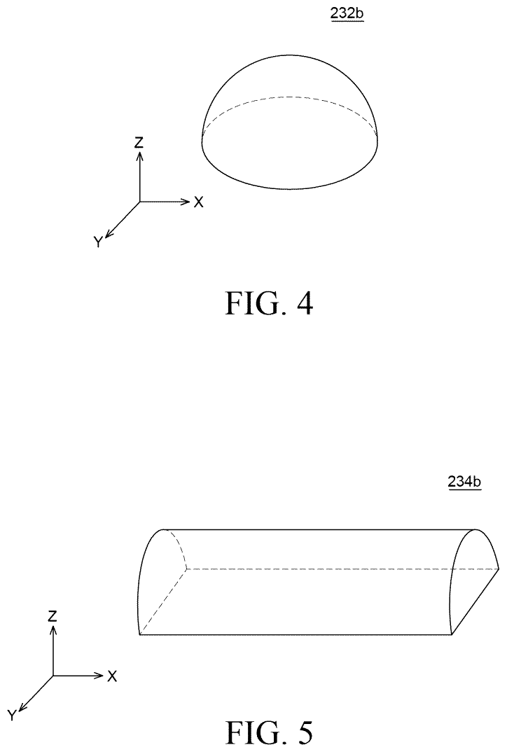

Hereinafter, an operation of selectively implementing a first mode which is a wide-view angle mode and a second mode which is a narrow-view angle mode will be described in detail with reference to FIGS. 4 to 6 jointly.

First, FIG. 4 is a view schematically illustrating a second portion of a first lens in the display apparatus according to an example embodiment of the present disclosure. FIG. 5 is a view schematically illustrating a second portion of a second lens in the display apparatus according to an example embodiment of the present disclosure.

As illustrated in FIG. 4, the second part 232b of the first lens 232 as the half-spherical lens has a half-circular cross-section in an X direction and a Y direction. Accordingly, the second part 232b of the first lens 232 limits X-direction and Y-direction viewing angles.

For example, the first emission area EA1 equipped with the first lens 232 including the half-spherical second part 232b may have a narrow view of 30 degrees or less in all of up and down, and left and right directions.

On the contrary, as illustrated in FIG. 5, the second part 234b of the second lens 234 as the half-cylindrical lens has a rectangular cross-section in the X direction and has a half-circular cross-section in the Y direction. Accordingly, the second part 234b of the second lens 234 limits the Y-direction viewing angle, and a viewing angle of a longitudinal direction, i.e., the X direction of the second part 234b of the second lens 234 is not limited.

For example, the second emission area EA2 equipped with the second lens 234 including the half-cylindrical second part 234b may have a narrow view of 30 degrees or less in the up and down directions, and a wide view of 60 degrees or more in the left and right directions.

Accordingly, an up-down narrow-view angle mode and a left-right narrow-view angle mode may be implemented by driving the first emission area EA1, and the up-down narrow-view angle mode and the left-right wide-view angle mode may be implemented by driving the second emission area EA2.

That is, in the light emitting display apparatus according to an example embodiment of the present disclosure, the narrow view may be continuously provided in the up and down directions by the first and second lenses 232 and 234, and the wide-view angle mode and the narrow-view angle mode may be selectively implemented in the left and right directions.

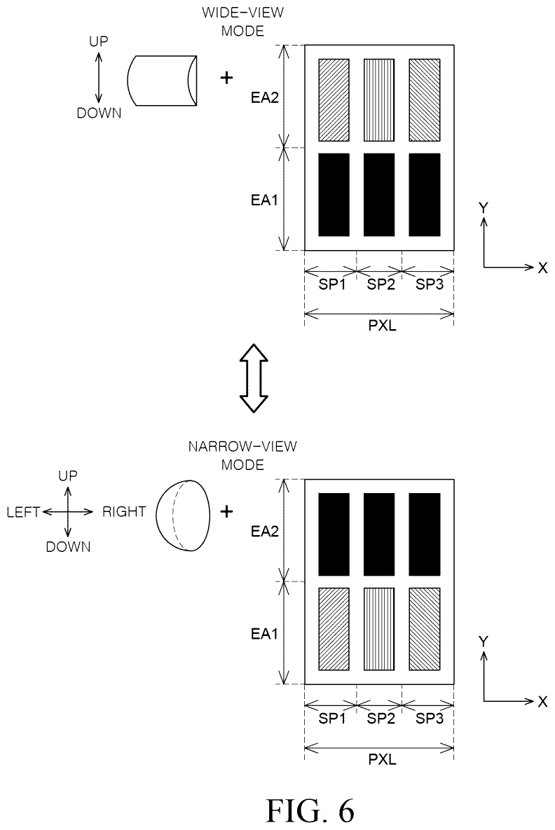

The left-right-direction wide-view angle mode and narrow-view angle mode will be described with reference to FIG. 6.

FIG. 6 is a view schematically illustrating operations of a wide-view angle mode and a narrow-view angle mode in the display apparatus according to an example embodiment of the present disclosure.

As illustrated in FIG. 6, one pixel PXL of the display apparatus according to an example embodiment of the present disclosure includes first to third subpixels SP1, SP2, and SP3, and each of the first to third subpixels SP1, SP2, and SP3 has a first emission area EA1 and a second emission area EA2.

A first lens 232 including a half-spherical second part 232b is provided to correspond to the first emission area EA1, and a second lens 234 including a half-cylindrical second part 234b is provided to correspond to the second emission area EA2.

In an operation in a wide-view angle mode, the first light emitting diode De1 of the first emission area EA1 becomes an off state, the second light emitting diode De2 of the second emission area EA2 becomes an on state, and a viewing angle of light emitted from the second light emitting diode De2 is limited in a Y direction, i.e., an up-down direction by the second lens 234, and the light is output in an X direction, i.e., a left-right direction without the limitation of the viewing angle.

On the contrary, in an operation in a narrow-view angle mode, the first light emitting diode De1 of the first emission area EA1 becomes the on state, the second light emitting diode De2 of the second emission area EA2 becomes the off state, and a viewing angle of light emitted from the first light emitting diode De1 is output in an up-down direction and the left-right direction with the viewing angle being limited by the first lens 232.

As such, since the display apparatus according to an example embodiment of the present disclosure continuously has the narrow view in the up-down direction, it is possible to suppress that an image is reflected by a front window of a vehicle, which interferes with a driving view when the display apparatus is applied to the vehicle from interfering.

An image having a wide view in the left-right direction may be displayed in the wide-view angle mode and an image having a narrow view in the left-right direction may be displayed in the narrow-view angle mode, and both users at a driver's seat and a passenger seat may watch the image in the wide-view angle mode and one of the users at the driver's seat and the passenger seat may watch the image in the narrow-view angle mode, so the wide-view angle mode and the narrow-view angle mode may be selectively implemented in the left-right direction.

By applying the first lens 232 and the second lens 234, the luminance to the same area is increased by a light collection effect, so driving voltage may be lowered. Further, as each of the first part 232a of the first lens 232 and the first part 234a of the second lens 234 is filled in the opening OP of the optical gap layer 220, some light which may be incident on the side surface of the optical gap layer 220 and may be lost may be fully reflected and output in a front direction. Therefore, the light extraction efficiency and the luminance are improved. Consequently, since the first emission area EA1 and the second emission area EA2 may be driven by lowering the driving voltage, power consumption may be lowered, and heat dissipation is reduced, so life-spans of the plurality of light emitting diodes De1 and De2 may be improved. Further, by light efficiency improvement, sizes of the subpixels SP1, SP2, and SP3 may be minimized while maintaining the optical characteristics to be high, and as a result, a high-resolution display apparatus may be provided. Accordingly, the display apparatus according to an example embodiment of the present disclosure provides an effect of improving the optical characteristics and a display quality by simultaneously increasing the luminance and the viewing angle limitation efficiency which have a trade off relationship.

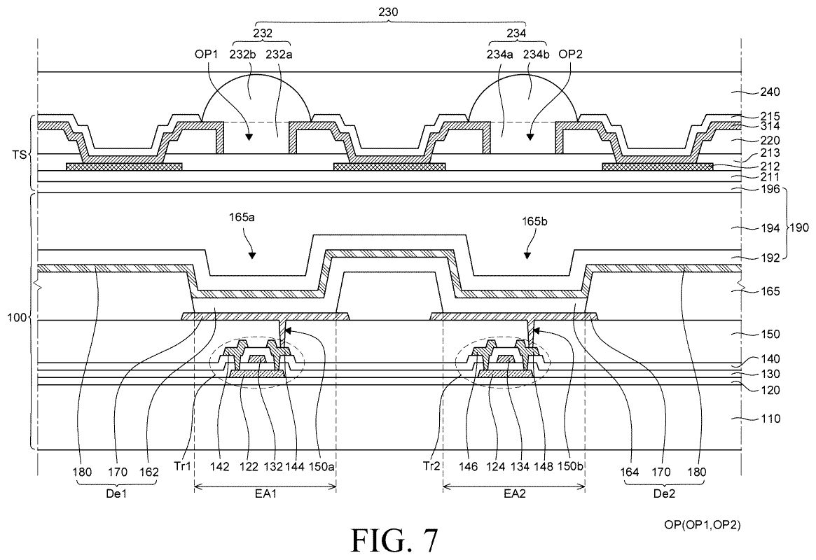

FIG. 7 is an enlarged cross-sectional view for one subpixel in a display apparatus according to another example embodiment of the present disclosure. Referring to FIG. 7, the display apparatus according to another example embodiment of the present disclosure is substantially the same as the display apparatus illustrated in FIGS. 1 to 6 in terms of the remaining configurations other than the layout structure of the touch electrode. As a result, a description of redundant components is omitted.

Referring to FIG. 7, the touch electrode 314 is disposed to cover the top surface of the bridge electrode 212, and the top surface and the side surface of the optical gap layer 220 exposed by the contact hole of the touch insulation layer 213 and the contact hole of the optical gap layer 220 formed to overlap with each other. That is, the touch electrode 314 may be disposed to cover all of a side wall surface of the optical gap layer 220 exposed by the contact hole, a top surface of the optical gap layer 220, and a side wall surface of the optical gap layer 220 exposed by the opening OP. Accordingly, at least a part of the touch electrode 314 covering the side wall surface of the optical gap layer 220 is in contact with the side surfaces of the first part 232a of the first lens 232 and the first part 234a of the second lens 234.

As described above, the touch electrode 314 may be formed as reflective metal including metal selected from aluminum (Al), silver (Ag), copper (Cu), and an alloy including one or more of them. Specifically, for example, the touch electrode 314 may be formed to include one or more metal selected from silver (Ag), aluminum (Al), or an aluminum-palladium-copper (APC) alloy.

Accordingly, even though some of the light emitted from the first light emitting diode De1 and the second light emitting diode De2 is incident in a side-surface direction of the optical gap layer 220, some light may be reflected by the touch electrode 314 disposed on the side wall surface of the optical gap layer 220 exposed by the opening OP and output toward the front. Accordingly, an amount of the light incident in the side-surface direction of the optical gap layer 220, which is fully reflected is further increased. Therefore, an effect is provided in which the light extraction efficiency of the display apparatus is maximized, so the luminance is further improved while maintaining the viewing angle blocking characteristics to be high.

Accordingly, according to another example embodiment of the present disclosure, a display apparatus may be provided, which has excellent viewing angle limitation characteristics while minimizing luminance loss. Further, the luminance is further increased compared to a display apparatus having the same area, so the driving voltage may be lowered. Further, since the first emission area EA1 and the second emission area EA2 may be driven by lowering the driving voltage, power consumption may also be lowered, and heat dissipation is reduced, so life-spans of the plurality of light emitting diodes De1 and De2 may be improved. Further, sizes of the subpixels SP1, SP2, and SP3 may be minimized while maintaining the optical characteristics to be high, and as a result, a high-resolution display apparatus may be provided.

The example embodiments of the present disclosure can also be described as follows:

According to an aspect of the present disclosure, a display apparatus comprises a substrate; a plurality of light emitting diodes disposed on the substrate; a touch sensor disposed on the plurality of light emitting diodes; and a plurality of optical members disposed on the touch sensor, wherein the touch sensor includes a plurality of bridge electrodes disposed on the plurality of light emitting diodes, an optical gap layer disposed on the bridge electrode and expose at least a part of each of the plurality of bridge electrodes, and a touch electrode disposed to be in contact with each of the plurality of exposed bridge electrodes, and the optical gap layer includes a plurality of openings corresponding to the plurality of light emitting diodes, respectively, and the plurality of optical members is disposed to fill the plurality of openings, respectively.

Each of the plurality of optical members may include a first part filling the opening and a second part covering the first part.

The second part may cover the first part and at least a part of the optical gap layer adjacent to the opening.

A plurality of subpixels may be defined on the substrate, each of the plurality of subpixels may include a first light emitting diode and a second light emitting diode disposed on the substrate, and the plurality of optical members may include a first optical member that reflects light from the first light emitting diode and a second optical member that refracts light from the second light emitting diode.

The display apparatus may further comprises a bank disposed on the substrate to correspond to spaces between the subpixels adjacent to each other and between the first light emitting diode and the second light emitting diode, wherein the plurality of bridge electrodes and the touch electrode may be disposed to correspond to the bank, and the first optical member may be disposed to overlap the first light emitting diode and the second optical member may be disposed to overlap the second light emitting diode.

A second part of the first optical member may be a half-spherical lens, and a second part of the second optical member may be a half-cylindrical lens.

The plurality of openings may include a first opening corresponding to the first light emitting diode and a second opening corresponding to the second light emitting diode.

A first part of the first optical member may be disposed to fill the first opening, and a first part of the second optical member may be disposed to fill the second opening.

A plane shape of the first opening may be a circular shape, and a plane shape of the second opening may be a rectangular shape.

A straight distance from a bottom surface of the optical member to a corresponding top surface of the light emitting diode may be larger than a width of an emission region of each of the plurality of light emitting diodes.

An end of the optical gap layer, which is in contact with the touch electrode may have a step shape.

The optical gap layer may contain at least one of acrylic resin, siloxane-based resin, polyimide-based resin, polyamide-based resin, cycloolefin-based resin, polyester-based resin, epoxy resin, silicon-based resin and fluorine-based resin.

The optical member may include an acrylic resin.

The optical member may further include at least one repetition unit among repetition units represented by Formulas 1 to 4 below:

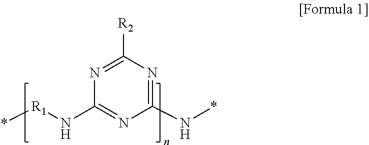

In Formula 1 above, R₁ may be selected from a linear alkyl group, a branched alkyl group, a cyclo alkyl group, and an aryl group, and R₂ may be selected from the linear alkyl group or the branched alkyl group, and n may be an integer of 1 or more and 100 or less.

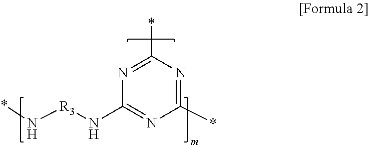

In Formula 2 above, R₃ may be selected from the linear alkyl group, the branched alkyl group, the cyclo alkyl group, and the aryl group, and m may be the integer of 1 or more and 100 or less.

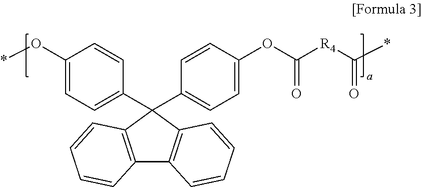

In Formula 3 above, R₄ may be selected from the linear alkyl group, the branched alkyl group, or the aryl group, and a may be the integer of 1 or more and 100 or less.

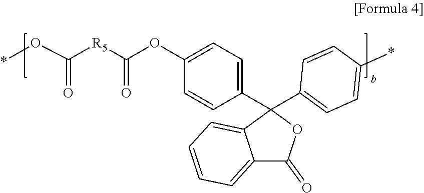

In Formula 4 above, R₅ may be selected from the linear alkyl group, the branched alkyl group, or the aryl group, and b may be the integer of 1 or more and 100 or less.

The touch electrode may be disposed to cover a top surface and a side surface of the optical gap layer, and may be in contact with a side surface of the first part of the optical member.

The touch electrode may include metal selected from aluminum, silver, copper, and an alloy including at least one thereof.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display apparatus comprising:
a substrate;
a plurality of light emitting diodes disposed on the substrate;
a touch sensor disposed on the plurality of light emitting diodes; and
a plurality of optical members disposed on the touch sensor,
wherein the touch sensor includes a plurality of bridge electrodes disposed on the plurality of light emitting diodes, an optical gap layer disposed on the bridge electrode and expose at least a part of each of the plurality of bridge electrodes, and a touch electrode disposed to be in contact with each of the plurality of exposed bridge electrodes, and
the optical gap layer includes a plurality of openings corresponding to the plurality of light emitting diodes, respectively, and the plurality of optical members is disposed to fill the plurality of openings, respectively.

2. The display apparatus of claim 1, wherein each of the plurality of optical members includes a first part filling the opening and a second part covering the first part.

3. The display apparatus of claim 2, wherein the second part covers the first part and at least a part of the optical gap layer adjacent to the opening.

4. The display apparatus of claim 2, wherein a plurality of subpixels is defined on the substrate, each of the plurality of subpixels includes a first light emitting diode and a second light emitting diode disposed on the substrate, and the plurality of optical members includes a first optical member that reflects light from the first light emitting diode and a second optical member that refracts light from the second light emitting diode.

5. The display apparatus of claim 4, further comprising:
a bank disposed on the substrate to correspond to spaces between the subpixels adjacent to each other and between the first light emitting diode and the second light emitting diode,
wherein the plurality of bridge electrodes and the touch electrode are disposed to correspond to the bank, and the first optical member is disposed to overlap the first light emitting diode and the second optical member is disposed to overlap the second light emitting diode.

6. The display apparatus of claim 5, wherein a second part of the first optical member is a half-spherical lens, and a second part of the second optical member is a half-cylindrical lens.

7. The display apparatus of claim 4, wherein the plurality of openings includes a first opening corresponding to the first light emitting diode and a second opening corresponding to the second light emitting diode.

8. The display apparatus of claim 7, wherein a first part of the first optical member is disposed to fill the first opening, and a first part of the second optical member is disposed to fill the second opening.

9. The display apparatus of claim 7, wherein a plane shape of the first opening is a circular shape, and a plane shape of the second opening is a rectangular shape.

10. The display apparatus of claim 1, wherein a straight distance from a bottom surface of the optical member to a corresponding top surface of the light emitting diode is larger than a width of an emission region of each of the plurality of light emitting diodes.

11. The display apparatus of claim 1, wherein an end of the optical gap layer, which is in contact with the touch electrode has a step shape.

12. The display apparatus of claim 1, wherein the optical gap layer contains at least one of acrylic resin, siloxane-based polyimide-based resin, resin, polyamide-based resin, cycloolefin-based resin, polyester-based resin, epoxy resin, silicon-based resin and fluorine-based resin.

13. The display apparatus of claim 1, wherein the optical member includes an acrylic resin.

14. The display apparatus of claim 13, wherein the optical member further includes at least one repetition unit among repetition units represented by Formulas 1 to 4 below: 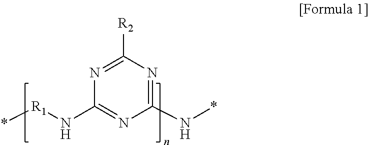
wherein in Formula 1 above, R₁ is selected from a linear alkyl group, a branched alkyl group, a cyclo alkyl group, and an aryl group, and R₂ may be selected from the linear alkyl group or the branched alkyl group, and n is an integer of 1 or more and 100 or less, 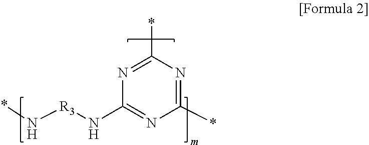
wherein in Formula 2 above, R₃ is selected from the linear alkyl group, the branched alkyl group, the cyclo alkyl group, and the aryl group, and m is the integer of 1 or more and 100 or less, 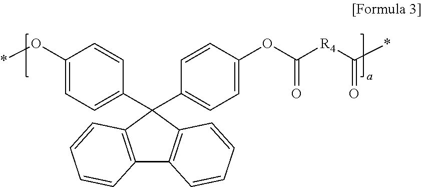
wherein in Formula 3 above, R₄ is selected from the linear alkyl group, the branched alkyl group, or the aryl group, and a is the integer of 1 or more and 100 or less, 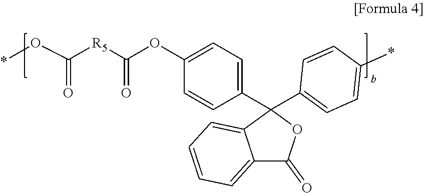
wherein in Formula 4 above, R₅ is selected from the linear alkyl group, the branched alkyl group, or the aryl group, and b is the integer of 1 or more and 100 or less.

15. The display apparatus of claim 2, wherein the touch electrode is disposed to cover a top surface and a side surface of the optical gap layer, and is in contact with a side surface of the first part of the optical member.

16. The display apparatus of claim 1, wherein the touch electrode includes metal selected from aluminum, silver, copper, and an alloy including at least one thereof.
